(19) United States
(12) Patent Application Publication
(10) Pub. No.: US 2015/0091133 A1
(43) Pub. Date: Apr. 2, 2015

(54) SEMICONDUCTOR DEVICE AND METHOD FOR FABRICATING THE SAME

(71) Applicant: Samsung Electronics Co., Ltd., Suwon-si (KR)

(72) Inventors: Kyu-Ho Cho, Hwaseong-si (KR); Hyun-Jeong Yang, Hwaseong-si (KR); Se-Hoon Oh, Hwaseong-si (KR); Yong-Jae Lee, Incheon (KR); Ki-Vin IM, Seongnam-si (KR); Jae-Soon Lim, Seoul (KR); Han-Jin Lim, Seoul (KR); Jae-Wan Chang, Seoul (KR); Chang-Hwa Jung, Seoul (KR)

(21) Appl. No.: 14/315,770

(22) Filed: Jun. 26, 2014

(30) Foreign Application Priority Data
Sep. 30, 2013 (KR) 10-2013-0116462

(51) Int. Cl. H01L 49/02

(52) U.S. Cl. CPC H01L 28/75
USPC 257/532

(57) ABSTRACT

In a semiconductor device and in methods of formation thereof, a semiconductor device comprises a substrate, a lower electrode on the substrate, and a dielectric layer on the lower electrode. An adhesion layer is positioned on the dielectric layer and an upper electrode is positioned on the adhesion layer. The adhesion layer contacts the dielectric layer and the upper electrode, and comprises a conductive material.

### CROSS-REFERENCE TO RELATED APPLICATIONS

This application is based on and claims priority from Korean Patent Application No. 10-2013-0116462, filed on Sep. 30, 2013 in the Korean Intellectual Property Office, the disclosure of which is incorporated herein in its entirety by reference.

### BACKGROUND

The present inventive concepts relate a semiconductor devices and methods for fabricating the same.

Along with the desire for ever more high-density integration of semiconductor memory devices, the design rule is reduced, and the area that is occupied by a unit memory cell in a memory device is gradually decreased. Particularly, in a DRAM device that is composed of one access transistor and one cell capacitor to store data in the capacitor of the unit cell, the area occupied by the capacitor is reduced. However, along with that reduction in size, a minimum capacitance, which is necessary for the input/output characteristics or reproduction characteristics of the memory device, must be maintained. Accordingly, in order to achieve the high density integration of the semiconductor memory device, there is a need for a method that can maintain or increase capacitance in a reduced space.

As size is reduced, if a capacitor dielectric layer is made to have a reduced thickness, leakage current characteristics may become weak, and thus it is required to use a dielectric layer having a relatively high dielectric constant (high-k). If a high-k layer is used as a dielectric in the capacitor, a layer having low dielectric constant (low-k) can be formed between the high-k layer and a polycrystalline silicon layer of the upper electrode. This can offset the desired increase in capacitance. Accordingly, MIM (Metal-Insulator-Metal) have been investigated and have become popular as an alternative to the MIS (Metal-Insulator-Semiconductor) capacitor. Particularly, in order to widen the surface area of electrodes that constitute the capacitor, a three-dimensional (3D) structure has been proposed, and a cylinder-type MIM capacitor has been employed.

### SUMMARY

The present inventive concepts provide semiconductor devices which further include a conductive adhesion layer to improve the adhesion characteristics between an electrode and a dielectric layer in fabricating MIM capacitors.

The present inventive concepts further provide a methods for fabricating semiconductor devices which further include a conductive adhesion layer to improve the adhesion characteristics between an electrode and a dielectric layer in fabricating MIM capacitors.

Additional advantages, subjects, and features of the inventive concept will be set forth in part in the description which follows and in part will become apparent to those having ordinary skill in the art upon examination of the following or may be learned from practice of the inventive concepts.

In one aspect, a semiconductor device comprises: a substrate; a lower electrode on the substrate; a dielectric layer on the lower electrode; an adhesion layer on the dielectric layer; and an upper electrode on the adhesion layer, wherein the adhesion layer contacts the dielectric layer and the upper electrode, and comprises a conductive material.

In some embodiments, an upper surface of the adhesion layer is evenly formed to adhere to a lower surface of the upper electrode.

In some embodiments, the conductive material has a band gap that is equal to or less than about 3.5 eV.

In some embodiments, the conductive material comprises oxide.

In some embodiments, the conductive material comprises NbOx or NbTiOx, where x is a real number that is equal to or larger than 2.

In some embodiments, the adhesion layer comprises a composite layer.

In some embodiments, at least one of the lower electrode and the upper electrode in turn comprises at least one of Ru, Ir, or Pt.

In some embodiments, the dielectric layer comprises a high-k material.

In another aspect, a semiconductor device comprises: a substrate; a conductive lower electrode on the substrate and having a 3D structure; a conformal dielectric layer on the lower electrode and including a high-k material; an conformal adhesion layer on the dielectric layer; and a conductive upper electrode on the conformal adhesion layer, wherein the conformal adhesion layer contacts the conformal dielectric layer and the upper electrode, and comprises a conductive material.

In some embodiments, an upper surface of the conformal adhesion layer is evenly formed to adhere to a lower surface of the upper electrode.

In some embodiments, the conductive material has a band gap that is equal to or less than about 3.5 eV.

In some embodiments, the conductive material comprises oxide.

In some embodiments, the conductive material comprises NbOx or NbTiOx, where x is a real number that is equal to or larger than 2.

In some embodiments, the conformal adhesion layer comprises a composite layer.

In some embodiments, at least one of the lower electrode and the upper electrode in turn comprises at least one of Ru, Ir, or Pt.

In another aspect, a capacitor structure comprises: a conductive lower electrode having a 3D structure on a substrate, the 3D structure including vertical portions that extend in a vertical direction of extension, relative to a horizontal direction of extension of the substrate; a conformal dielectric layer on the lower electrode and including a high-k material, the conformal dielectric layer covering at least the vertical portions of the 3D structure; an conformal adhesion layer on, and in contact with, the dielectric layer, the conformal adhesion layer covering at least portions of the conformal dielectric layer that in turn cover the vertical portions of the 3D structure, the conformal adhesion layer comprising a conductive material having an RMS surface roughness of less than about 1 nm; and a conductive upper electrode on, and in contact with, the conformal adhesion layer.

In some embodiments, the conductive material has a band gap that is equal to or less than about 3.5 eV.

In some embodiments, the conductive material comprises oxide.

In some embodiments, the conductive material comprises NbOx or NbTiOx, where x is a real number that is equal to or larger than 2.

In some embodiments, the conformal adhesion layer comprises a composite layer.

### BRIEF DESCRIPTION OF THE DRAWINGS

The above and other objects, features and advantages of the present inventive concepts will be more apparent from the following detailed description taken in conjunction with the accompanying drawings, in which:

FIG. 1 is a circuit diagram of a unit cell of a DRAM device;

FIG. 2 is a cross-sectional view of a semiconductor device according to an embodiment of the present inventive concepts;

FIG. 3 is a cross-sectional view of a semiconductor device according to another embodiment of the present inventive concepts;

FIGS. 4 to 8 are views of intermediate steps explaining a method for fabricating a semiconductor device according to an embodiment of the present inventive concepts;

FIGS. 9 to 13 are views of intermediate steps of a method for fabricating a semiconductor device according to another embodiment of the present inventive concepts;

FIG. 14 is a block diagram of an electronic system including a semiconductor device according to some embodiments of the present inventive concepts;

FIG. 15 is a block diagram illustrating an example of a memory card including a semiconductor device according to some embodiments of the present inventive concepts; and

FIGS. 16 and 17 are views of an exemplary semiconductor system to which a semiconductor device according to some embodiments of the present inventive concepts can be applied.

### DETAILED DESCRIPTION OF EMBODIMENTS

The present inventive concepts will now be described more fully hereinafter with reference to the accompanying drawings, in which preferred embodiments of the inventive concept are shown. This inventive concept may, however, be embodied in different forms and should not be construed as limited to the embodiments set forth herein. Rather, these embodiments are provided so that this disclosure will be thorough and complete, and will filly convey the scope of the inventive concept to those skilled in the art. The same reference numbers indicate the same components throughout the specification. In the attached figures, the thickness of layers and regions is exaggerated for clarity.

It will also be understood that when a layer is referred to as being “on” another layer or substrate, it can be directly on the other layer or substrate, or intervening layers may also be present. In contrast, when an element is referred to as being “directly on” another element, there are no intervening elements present.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the inventive concept (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this inventive concept belongs. It is noted that the use of any and all examples, or exemplary terms provided herein is intended merely to better illuminate the inventive concept and is not a limitation on the scope of the inventive concept unless otherwise specified. Further, unless defined otherwise, all terms defined in generally used dictionaries may not be overly interpreted.

The present inventive concepts will be described with reference to perspective views, cross-sectional views, and/or plan views, in which preferred embodiments of the inventive concept are shown. Thus, the profile of an exemplary view may be modified according to manufacturing techniques and/or allowances. That is, the embodiments of the inventive concept are not intended to limit the scope of the present inventive concept but cover all changes and modifications that can be caused due to a change in manufacturing process. Thus, regions shown in the drawings are illustrated in schematic form and the shapes of the regions are presented simply by way of illustration and not as a limitation.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

A semiconductor device to be described hereinafter has a structure that includes an adhesion layer to supplement deterioration of the characteristics of a MIM (Metal-Insulator-Metal) capacitor due to weakening of the adhesion characteristics between an electrode and a dielectric layer in fabricating the MIM capacitor using metal material as the electrode.

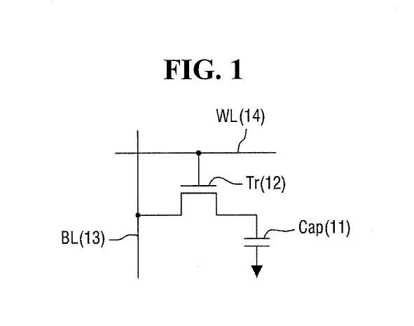

FIG. 1 is a circuit diagram of a unit cell of a DRAM device.

A unit cell of a DRAM device may have various configurations. In some embodiments, as illustrated in FIG. 1, the unit cell is composed of one capacitor 11 and one transistor 12. The transistor 12 gate is connected to a word line 14. One source/drain region that constitutes the transistor 12 is connected to a bit line 13. The other source/drain region that constitutes the transistor 12 is connected to the capacitor 11. The present inventive concept relates to the capacitor 11 of the unit cell.

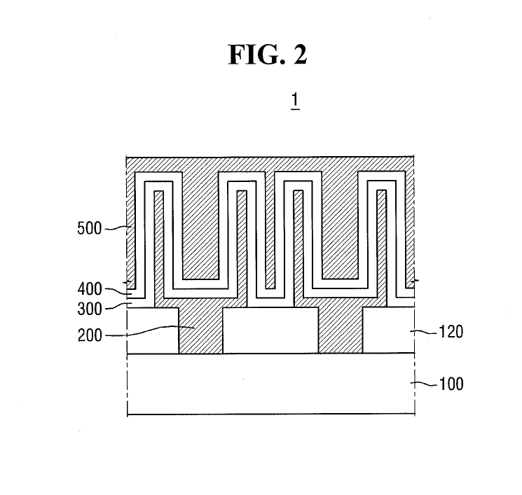

FIG. 2 is a cross-sectional view of a semiconductor device according to an embodiment of the present inventive concepts.

Referring to FIG. 2, a semiconductor device 1 according to an embodiment of the present inventive concepts includes a substrate 100, an interlayer insulating layer 120, a lower electrode 200, a dielectric layer 300, an adhesion layer 400, and an upper electrode 500.

A MIM capacitor is a capacitor having generally a metal-insulator-metal structure, and a MIM capacitor according to an embodiment of the present inventive concepts may be particularly used as a capacitor that stores information in a DRAM device.

In some embodiments, the substrate 100 may comprise one or more semiconductor materials selected from the group including Si, Ge, SiGe, GaP, GaAs, SiC, SiGeC, InAs, and InP. Further, in some embodiments, the substrate 100 may comprise a SOI (Silicon On Insulator) substrate. Further, in some embodiments, the substrate 100 may comprise a rigid substrate, such as a glass substrate for a display, or such as a flexible plastic substrate that comprises polyimide, polyester, polycarbonate, polyethersulfone, polymethylmethacrylate, polyethylenenaphthalate, or polyethyleneterephthalate.

In some embodiments, the substrate 100 may include unit elements required to form semiconductor elements, such as various kinds of active elements or passive elements. The unit elements may correspond to the DRAM device of FIG. 1. The substrate 100 may include isolation layers for isolating the unit elements from each other. The interlayer insulating layer 120 may be formed on the substrate 100 to cover the unit elements. Further, the substrate 100 may include conductive regions that are electrically connectable to the unit elements through the interlayer insulating layer 120.

In some embodiments, the interlayer insulating layer 120 may be formed on the substrate 100. The interlayer insulating layer 120 may be formed to have a contact hole for exposing a part of the substrate 100 in a region where the capacitor is formed. Metal may fill the contact hole to form a part of the lower electrode 200. In some embodiments, the interlayer insulating layer 120 may be formed using, for example, silicon oxide, such as BSG (BoroSilicate Glass), PSG (PhosphoSilicate Glass), BPSG (BoroPhosphoSilicate Glass), USG (Undoped Silicate Glass), TERS (TetraEthlyOrthoSilicate Glass), or HDP-CVD (High Density Plasma-CVD).

In some embodiments, the lower electrode 200 is formed on the substrate 100. Specifically, if the interlayer insulating layer 120 is formed, the lower electrode 200 is formed on the interlayer insulating layer 120 to fill the contact hole of the interlayer insulating layer 120. In some embodiments, the lower electrode 200 may have a three-dimensional (3D) structure, such as a cylinder type or a pillar type. The cylinder type lower electrode 200 may have various forms or shapes, including legs or arms that extend in a vertical direction of extension, relative to the horizontal direction of extension of the substrate. Since the lower electrode 200 has a 3D structure as described above, the effective area of the capacitor can be increased. Accordingly, the capacitance of the capacitor can be increased.

In some embodiments, the lower electrode 200 may comprise a metal having a high work function. In some embodiments, the lower electrode 200 may be made of, for example, a metal material, such as Ti, TiN, W, WN, Ta, TaN, TiAlN, TaSiN, TiSiN, TaAlN, Pt, Ru, or Ir. Further, in some embodiments, the lower electrode 200 may be made of noble-metal conductive oxide, such as PtO, RuO₂, or IrO₂, or conductive oxide, such as SRO(SrRuO₃), BSRO ((Ba, Sr)RuO₃), or CRO(CaRuO₃). These materials have the advantages that they have heightened electrical characteristics, such as leakage current characteristics, in a capacitor which utilizes a high-k material as a dielectric layer. Particularly, in the case of forming the lower electrode 200 with a metal material, such as TiN, TaN, WN, Ru, or Pt, which has high work function characteristics and superior anti-oxidation properties, formation of a low dielectric constant (low-k) material is suppressed and thus high capacitance can be secured when the dielectric layer 300 is deposited on the lower electrode 200. Further, a leakage current barrier is formed due to the presence of a hetero junction between the lower electrode 200 and the dielectric layer 300, and thus the leakage current characteristics of the resulting capacitor are improved.

In various embodiments, the lower electrode 200 may have a single-layer structure or a composite-layer structure. In order to deposit the lower electrode 200, an ALD (Atomic Layer Deposition) method or a CVD (Chemical Vapor Deposition) method, which has excellent step coverage, may be used. Alternatively, a PVD (Physical Vapor Deposition) method, a MOCVD (Metal Organic Chemical Vapor Deposition) method, or a PEALD (Plasma Enhanced Atomic Layer Deposition) method may be used.

The dielectric layer 300 is formed on the lower electrode 200. In a case where the lower electrode 200 is formed to have a 3D structure, the dielectric layer 300 may be formed to cover an outer surface of the lower electrode 200. For example, if the lower electrode 200 is shaped as a cylinder-type electrode, the dielectric layer 300 may be conformally formed to cover the outer surface of the lower electrode 200. In some embodiments, the dielectric layer 300 may comprise a high-k material. In some embodiments, the material that forms the dielectric layer 300 may comprise a material having a perovskite crystalline structure.

In some embodiments, the perovskite crystalline structure has the general relationship ABO₃, in which A and B are cations having different sizes, and may differ in accordance with the ratio of A to B. In one unit cell, A is positioned in the corner portion, B is positioned in the center, and oxygen atoms are positioned at the edge of each unit cell. In a complicated perovskite crystalline structure, quite various modified structures thereof can be provided depending on which material is provided as the B cation. The perovskite crystalline structure has ferroelectricity. A material having such a perovskite crystalline structure, for example, SrTiO₆ (STO), has stability and a high dielectric constant.

In some embodiments, the dielectric layer 300 may comprise one or more of, for example, a high-k material, such as (Ba, Sr)TiO₃ (BST), SrTiO₃, BaTiO₃, PZT, PLZT, Ba(Zr, Ti)O₃ (BZTO), or Sr(Zr, Ti)O₃) (SZTO), or may be made of a metal oxide, such as Ta₂O₅, Ta₂O₅N, Al₂O₅, HfO₂, ZrO₂, or TiO₂. In FIG. 2, the dielectric layer 300 is illustrated as a single layer, but is not limited thereto. The dielectric layer 300 may be deposited as a composite layer. For example, the dielectric layer 300 may be formed through lamination of a metal oxide layer on a metal nitride layer. If needed, the dielectric layer 300 may be formed with three or more layers. A passivation layer may be further formed on the dielectric layer 300. The passivation layer may be formed to come in contact with the dielectric layer 300, and may comprise a conductive layer having conductivity.

In order to deposit the dielectric layer 300, in some embodiments, an ALD method or a CVD method having excellent step coverage may be used. In addition, a PVD method, a MOCVD method, or a PEALD method may be used. Further, heat treatment or plasma processing for crystallizing the dielectric layer 300 may be performed.

The adhesion layer 400 is formed on the dielectric layer 300. The adhesion layer 400 is formed to come in contact with the dielectric layer 300 and the upper electrode 500. In particular, an upper surface of the adhesion layer 400 may be evenly formed to adhere to a lower surface of the upper electrode 500. If the adhesion layer 400 is not formed and the upper electrode 500 is formed directly on the dielectric layer 300, the surface roughness characteristics of the dielectric layer 300 become deteriorated to cause the adhesion characteristics between the dielectric layer 300 and the upper electrode 500 to also be deteriorated. The surface roughness characteristics of a thin film may be quantified using RMS (Root Mean Square) roughness. Since the RMS roughness of the dielectric layer 300 corresponds to several to several tens of nanometers, the adhesion characteristics between the dielectric layer 300 and the upper electrode 500 can be improved using a layer having the RMS roughness of 1 nm or less as the adhesion layer 400. As described above, in order to improve the RMS roughness characteristics of the adhesion layer 400, the adhesion layer 400 may be formed using oxide having high ratio of oxygen atoms. For example, the ratio of metal atoms to oxygen atoms of the adhesion layer 400 may be 1:2.5 or more.

According to an embodiment of the present inventive concepts, the adhesion layer 400 is formed using a material which has high work function and high adhesion characteristics, and has a band gap of about 3.5 eV or less. Further, the adhesion layer 400 should be conductive. For example, the adhesion layer 400 may comprise a material including NbOx or NbTiOx, where x is a real number that is equal to or larger than 2. That is, the adhesion layer 400 may be Nb₂O₅ or Nb₂TiO₅.

In some embodiments, the adhesion layer 400 may have a single layer structure or a composite layer structure. In order to deposit the adhesion layer 400, an ALD method or a CVD method having excellent step coverage may be used. In addition, a PVD method, a MOCVD method, or a PEALD method may be used to form the adhesion layer.

The upper electrode 500 is formed on the adhesion layer 400. Specifically, the upper electrode 500 may be formed on the entire substrate 100, or on the entire underlying structure, to fill a space in which the adhesion layer 400 is formed. In some embodiments, the upper electrode 500 may comprise a metal having high work function characteristics instead of a polycrystalline silicon electrode. In some embodiments, the upper electrode 500 may include, for example, a material having the work function of 5 eV or more. In some embodiments, the upper electrode 500 may be formed using a metal material, such as Pt, Ru, or Ir. Further, in some embodiments, the upper electrode 500 may comprise a noble-metal conductive oxide, such as PtO, RuO₂, or IrO₂, or conductive oxide, such as SRO (SrRuO₃), BSRO ((Ba, Sr)RuO₃), or CRO (CaRuO₃).

The upper electrode 500 may comprise a single layer structure or a composite layer structure. In order to deposit the upper electrode 500, an ALD method or a CVD method having excellent step coverage may be used. In addition, a PVD method, a MOCVD method, or a PEALD method may be employed.

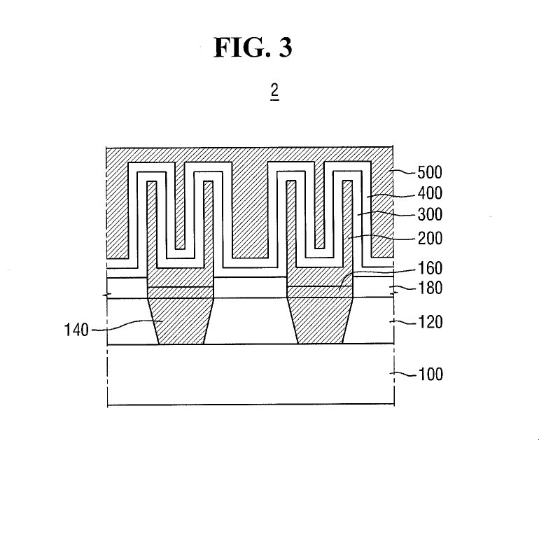

FIG. 3 is a cross-sectional view of a semiconductor device according to another embodiment of the present inventive concepts. For convenience in explanation, explanation of the portions that are substantially the same as those of the semiconductor device 1 according to an embodiment of the present inventive concepts will be omitted.

Referring to FIG. 3, a semiconductor device 2 according to another embodiment of the present inventive concepts includes a substrate 100, an interlayer insulating layer 120, a buried contact 140, an ohmic layer 160, an etch stop layer 180, a lower electrode 200, a dielectric layer 300, an adhesion layer 400, and an upper electrode 500.

FIG. 3 illustrates a DRAM device having a capacitor connected to a storage node contact plug by means of an ohmic layer that comprises metal silicide. However, it is apparent to those skilled in the art that the semiconductor device according to the present inventive concept can be applied to any other memory device having a capacitor structure connected to a lower structure by means of the ohmic layer that is made of metal silicide.

Referring to FIG. 3, the substrate 100 may be a semiconductor substrate, such as a silicon wafer. The substrate 100 may be divided into an active region where a conductive structure is arranged and a field region where an isolation layer that defines the active region is arranged. The conductive structure may include a plurality of gate structures arranged on the active region and source/drain regions formed through injection of conductive impurities into side portions of the gate structures. Further, the conductive structure may include a bit line contact that comes in contact with the drain region, a bit line connected to the bit line contact, and a storage node contact pad that comes in contact with the source region. The gate structure, the bit line contact, the storage node contact, and the bit line may be arranged to be electrically insulated from each other by a plurality of insulating layers.

The interlayer insulating layer 120 is arranged to cover the lower conductive structure and to have a flat upper surface, and may include a contact hole for exposing the storage node contact pad that is connected to the source region.

In some embodiments, the buried contact 140 includes polycrystalline silicon doped with As or P, and is formed by burying the contact hole. The buried contact 140 may come in contact with the lower storage node contact. An upper surface of the buried contact 140 is planarized to share an upper surface with that of the interlayer insulating layer 120.

The ohmic layer 160 is arranged on the surface of the buried contact 140, and may include a metal silicide layer that is formed through silicide reaction between the metal and silicon of the buried contact 140. In this case, the ohmic layer 160 may have a thermally stable crystal structure through a first heat treatment that is performed at a relatively low temperature and a second heat treatment that is performed instantaneously and locally at a relatively high temperature.

For example, in some embodiments, the ohmic layer 160 may include mono nickel silicide (NiSi) or mono nickel platinum silicide (NiPtSi). Nickel silicide offers superior resistivity characteristics in comparison to platinum silicide or cobalt silicide, and has relatively low silicon consumption rate at high temperature. Accordingly, nickel silicide can prevent the increase of surface resistance due to condensation of the silicide layer, and maintain sufficiently low contact resistance between the lower electrode 200 and the buried contact 140.

In particular, the nickel (or nickel platinum) silicide that forms the ohmic layer 160 may be instantaneously melted through a millisecond annealing process and then be recrystallized to have a thermally stable crystal structure. Accordingly, the thermal weakness of the nickel (or nickel platinum) silicide is sufficiently removed, and thus the contact resistance between the buried contact 140 and the lower electrode 200 can be improved.

In some embodiments, the etch stop layer 180 may include silicon nitride to protect the lower conductive structure in the process of forming the lower electrode 200. Other materials having similar characteristics are equally applicable.

The lower electrode 200 may come in contact with the buried contact 140 through the medium of the ohmic layer 160. Accordingly, the lower electrode 200 may be electrically connected to the source region of the lower structure through the buried contact 140 and the storage node contact pad.

In the DRAM memory device according to an embodiment of the present inventive concepts, since the ohmic layer 160 that is arranged between the buried contact 140 and the lower electrode 200 is provided as a thermally stable nickel silicide layer or nickel platinum silicide layer, any increase in surface resistance due to the condensation of the silicide layer can be suppressed, and the contact resistance between the lower electrode 200 and the buried contact 140 can be minimized. Accordingly, the operating speed of the DRAM memory device can be improved.

Hereinafter, a method for fabricating a semiconductor device according to some embodiments of the present inventive concepts will be described.

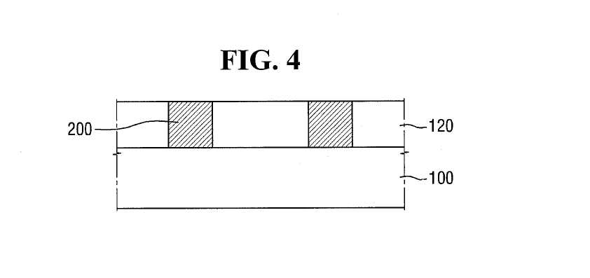

FIGS. 4 to 8 are views of intermediate steps explaining a method for fabricating a semiconductor device according to an embodiment of the present inventive concept.

Referring to FIG. 4, an interlayer insulating layer 120 is first formed on a substrate 100. A pattern of the interlayer insulating layer 120 is formed through formation of a contact hole for exposing a part of the substrate 100. A part of a lower electrode 200 of a capacitor is formed to fill the contact hole.

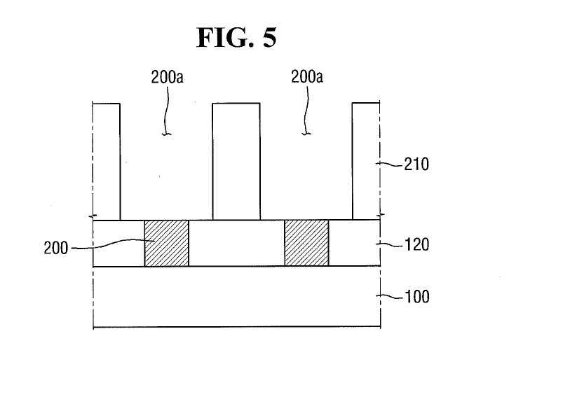

Then, referring to FIG. 5, a contact hole 200a for forming the remaining portion of the lower electrode 200 is formed on the interlayer insulating layer 120. After the interlayer insulating layer 210 is formed, the contact hole 200a for exposing a position in which the lower electrode 200 is to be formed is provided.

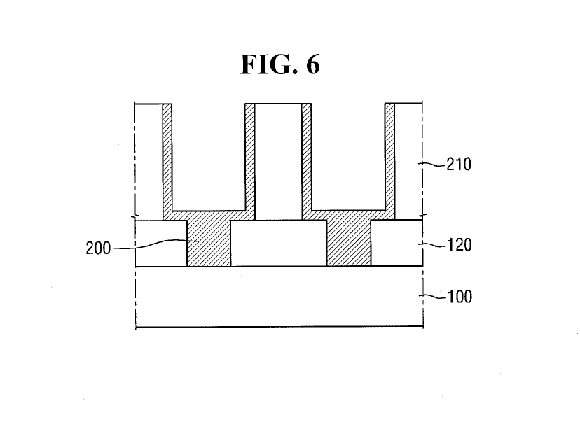

Then, referring to FIG. 6, the remaining portion of the lower electrode 200 is formed by depositing a material that forms the lower electrode 200 on a side wall and a lower surface of the contact hole 200a. FIG. 6 illustrates that the lower electrode 200 is formed in a cylinder type. However, it is apparent to those skilled in the art that the lower electrode 200 may have other 3D structures that are equally applicable to the inventive concepts. In this case, the lower electrode 200 may be deposited using an ALD method, a CVD method, a PVD method, a MOCVD method, or a PEALD method, or other applicable method.

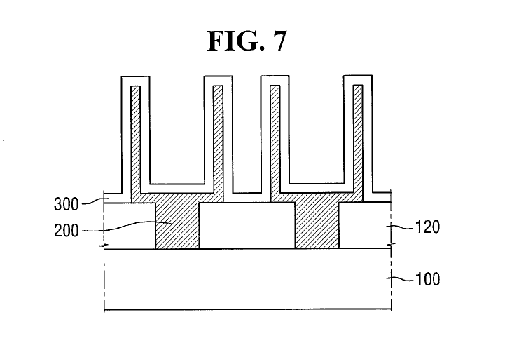

Referring to FIG. 7, after the interlayer insulating layer 210 is removed, a dielectric layer 300 is formed on the lower electrode 200. In the case where the lower electrode 200 is formed to have a cylinder type 3D structure, the dielectric layer 300 may be conformally formed on the lower electrode 200. That is, the dielectric layer 300 may be formed on the inner and outer surfaces of the lower electrode 200 to surround the cylinder, or vertical walls, and inner horizontal portion, that forms the lower electrode 200. In some embodiments, the dielectric layer 300 may be formed of a high-k material, and for example, may be formed of metal oxide including oxygen. In some embodiments, the dielectric layer 300 may comprise a single layer of hafnium oxide or a double layer in which an aluminum oxide layer and a hafnium oxide layer are laminated.

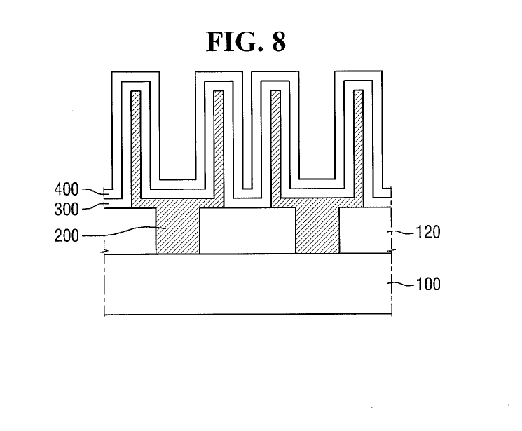

Referring to FIG. 8, an adhesion layer 400 is formed on the dielectric layer 300. The adhesion layer 400 may be conformally formed on the dielectric layer 300. That is, the adhesion layer 400 may be formed on the inner and outer portions of the dielectric layer 300 to surround the dielectric layer 300. In other words, in some embodiments, the adhesion layer 400 is formed conformally on exposed surfaces of the dielectric layer 300. An upper surface of the adhesion layer 400 may be evenly formed to adhere to a lower surface of an upper electrode 500 to be formed. In some embodiments, the adhesion layer 400 may be Nb₂O₅ or Nb₂TiO₅. In some embodiments, the adhesion layer 400 may have a single layer structure or a composite layer structure. In some embodiments, the adhesion layer 400 may be formed using an ALD method, a CVD method, a PVD method, a MOCVD method, or a PEALD method.

Returning to FIG. 2, the upper electrode 500 is formed on the adhesion layer 400. The upper electrode 500 may be formed on the whole substrate 100 to cover the whole adhesion layer 400. The upper electrode 500 may have a single layer structure or a composite layer structure. The upper electrode 500 may be formed using an ALD method, a CVD method, a PVD method, a MOCVD method, or a PEALD method.

In some embodiments, the upper electrode 500 may be composed of a silicon series material layer and an upper metal layer. In some embodiments, the silicon series material layer may comprise a material which can form metal silicide through reaction with the upper metal layer and which can form metal silicide at low temperature. The silicon series material layer may be formed of silicon germanium (SiGe) or amorphous silicon. In a case where the silicon series material layer is formed of silicon germanium, it may be doped with an impurity (e.g., boron). The silicon germanium layer or the amorphous silicon layer, which is the silicon series material layer, can be deposited at low temperature (e.g., 460° C.) as compared with the deposition temperature (e.g., 530° C.) of the poly silicon layer. After the silicon series material layer and the upper metal layer are formed, the silicon series material layer and the upper metal layer are silicidated using a heat treatment process. In some embodiments, the heat treatment can be performed at low temperature that is equal to or lower than 450° C., and be performed in a single step or in a multi-step.

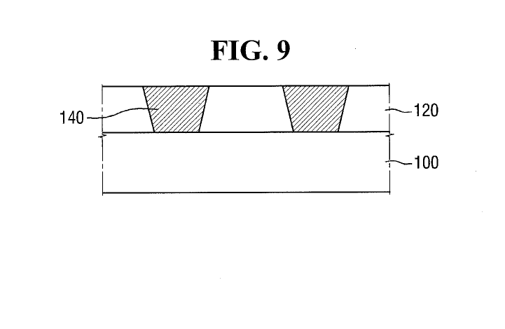

FIGS. 9 to 13 are views of intermediate steps explaining a method for fabricating a semiconductor device according to another embodiment of the present inventive concepts. For convenience in explanation, explanation of the portions that are substantially the same as those of the method for fabricating a semiconductor device according to an embodiment of the present inventive concept will be omitted.

Referring to FIG. 9, on a substrate 100 on which lower conductive structures, such as gate structures, are arranged, an interlayer insulating layer 120 is formed to cover the lower conductive structures so that the lower conductive structures are insulated from each other. Further, in the substrate 100, an isolation layer that defines an active region may be formed using an STI (Shallow Trench Isolation) process. On the interlayer insulating layer 120, a storage node contact hole is formed in a position where a buried contact 140 is to be formed, and the buried contact 140 is formed to fill the storage node contact hole. The buried contact 140 penetrates the interlayer insulating layer 120 and is connected to the lower storage node contact, and an upper surface of the buried contact 140 may be formed with the same height as the surface of the interlayer insulating layer 120.

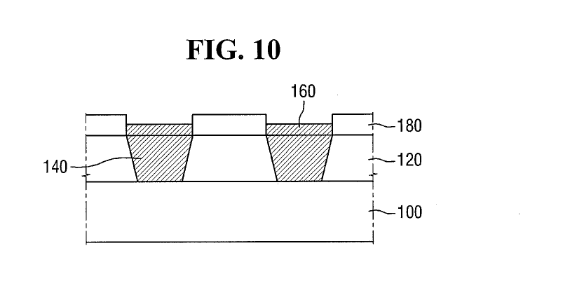

Then, referring to FIG. 10, an etch stop layer 180 is formed on the interlayer insulating layer 120, and portions of the etch stop layer 180 are removed to expose the buried contact. An ohmic layer 160 that is electrically connected to a lower electrode 200 is formed on the exposed buried contact 140. In some embodiments, the ohmic layer 160 may be formed through an MSA process. Since the ohmic layer 160 has a thermally stable structure, condensation of the ohmic layer 160 can be suppressed while the subsequent process including a high-temperature process is performed. Accordingly, the surface resistance of the ohmic layer can be prevented from being increased after the high-temperature process.

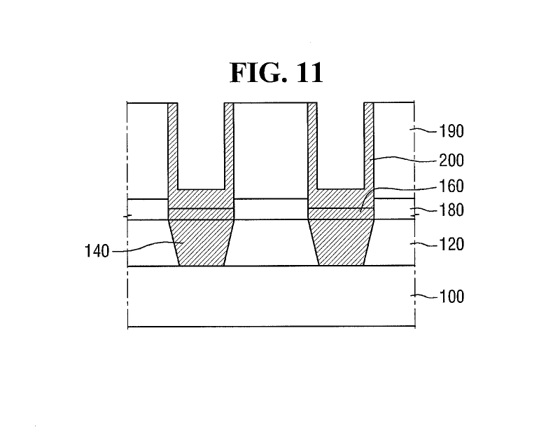

Then, referring to FIG. 11, after an interlayer insulating layer 190 is formed on the etch stop layer 180, a contact hole is formed to expose the position where the lower electrode 200 is to be formed. The lower electrode 200 is formed by depositing a material that forms the lower electrode 200 on an inner side wall and a lower surface of the contact hole. FIG. 11 illustrates that the lower electrode 200 is formed in a cylinder type shape. However, it is apparent to those skilled in the art that the lower electrode 200 may have other 3D structures that are equally applicable to the inventive concepts. In this case, the lower electrode 200 may be deposited using an ALD method, a CVD method, a PVD method, a MOCVD method, or a PEALD method.

After the lower electrode 200 is formed, an additional heat treatment process may be further performed. The heat treatment process may be performed in a furnace without gas or with inert gas, such as nitrogen gas or argon gas, at 550° C. to 650° C. In this case, by supplying ammonia gas, impurities in the lower electrode 200 may be removed, or the mechanical stress generated by a nitride layer that forms the lower electrode 200 may be mitigated.

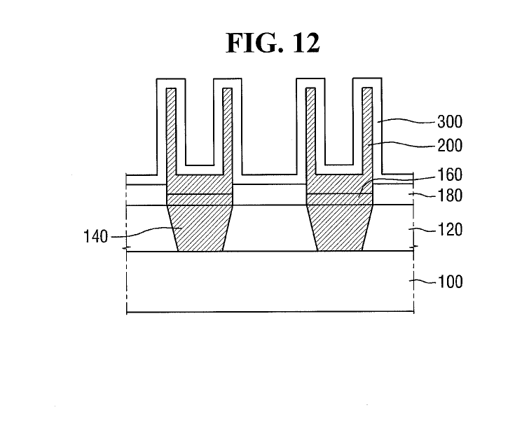

Then, referring to FIG. 12, after the interlayer insulating layer 190 is removed, a dielectric layer 300 is formed on the lower electrode 200. In the case where the lower electrode 200 is formed to have a cylinder type 3D structure, the dielectric layer 300 may be conformally formed on the lower electrode 200. That is, the dielectric layer 300 may be formed on the inner and outer exposed walls or vertical structured of the lower electrode 200 to surround the cylinder that forms the lower electrode 200. The dielectric layer 300 may be formed of a high-k material, and for example, may be formed of metal oxide including oxygen. The dielectric layer 300 may be a single layer of hafnium oxide or a double layer in which an aluminum oxide layer and a hafnium oxide layer are laminated.

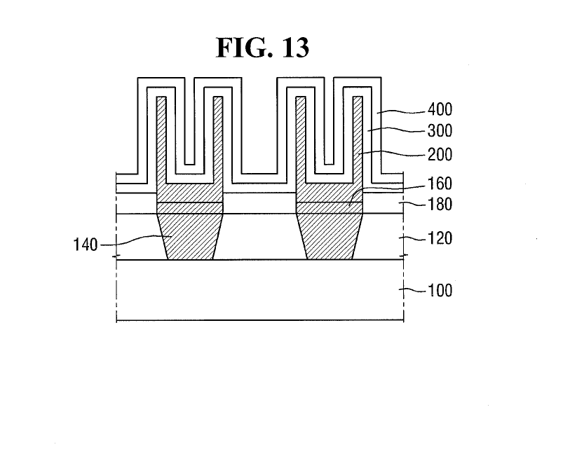

Referring to FIG. 13, an adhesion layer 400 is formed on the dielectric layer 300. The adhesion layer 400 may be conformally formed on the dielectric layer 300. That is, the adhesion layer 400 may be formed on inner and outer exposed surfaces of the dielectric layer 300 to surround any exposed portions of the dielectric layer 300. In some embodiments, an upper surface of the adhesion layer 400 may be evenly formed to adhere to a lower surface of an upper electrode 500. In some embodiments, the adhesion layer 400 may comprise Nb₂O₅ or Nb₂TiO₅. In some embodiments, the adhesion layer 400 may have a single layer structure or a composite layer structure. In some embodiments, the adhesion layer 400 may be formed using an ALD method, a CVD method, a PVD method, a MOCVD method, or a PEALD method.

The upper electrode 500 is formed on the adhesion layer 400. In some embodiments, upper electrode 500 may be formed on the entire substrate 100, or on entire regions of the substrate, or on the underlying capacitor structures, to cover the adhesion layer 400. The upper electrode 500 may have a single layer structure or a composite layer structure. The upper electrode 500 may be formed using an ALD method, a CVD method, a PVD method, a MOCVD method, or a PEALD method.

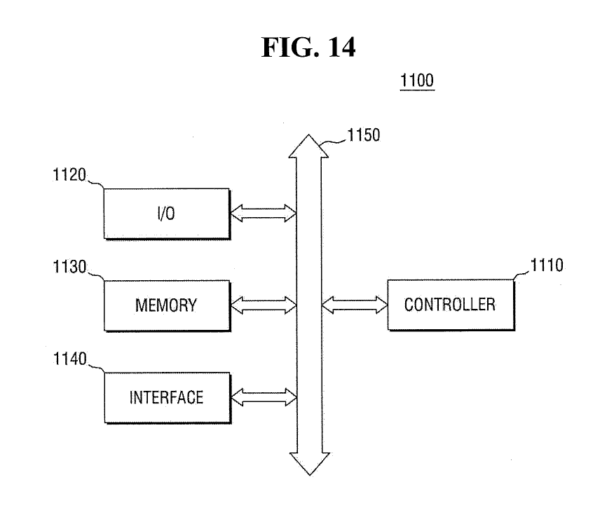

FIG. 14 is a block diagram of an electronic system including a semiconductor device according to some embodiments of the present inventive concept.

Referring to FIG. 14, an electronic system 1100 may include a controller 1110, an input/output (I/O) device 1120, a memory 1130, an interface 1140, and a bus 1150. The controller 1110, the I/O device 1120, the memory 1130 and/or the interface 1140 may be connected to each other through the bus 1150. The bus 1150 corresponds to paths through which data is transferred.

In some embodiments, the controller 1110 may include at least one of a microprocessor, a digital signal processor, a microcontroller, and logic elements that can perform similar functions. The I/O device 1120 may include a keypad, a keyboard, and a display device. The memory 1130 may store data and/or commands. The interface 1140 may function to transfer the data to a communication network or receive the data from the communication network. The interface 1140 may be of a wired or wireless type. For example, the interface 1140 may include an antenna or a wire/wireless transceiver. The semiconductor device according to embodiments of the present inventive concept may be provided in the memory 1130 or may be provided as a part of the controller 1110 or the I/O device 1120.

In some embodiments, the electronic system 1100 may be applied to a PDA (Personal Digital Assistant), a portable computer, a web tablet, a wireless phone, a mobile phone, a digital music player, a memory card, or all electronic devices that can transmit and/or receive information in wireless environments.

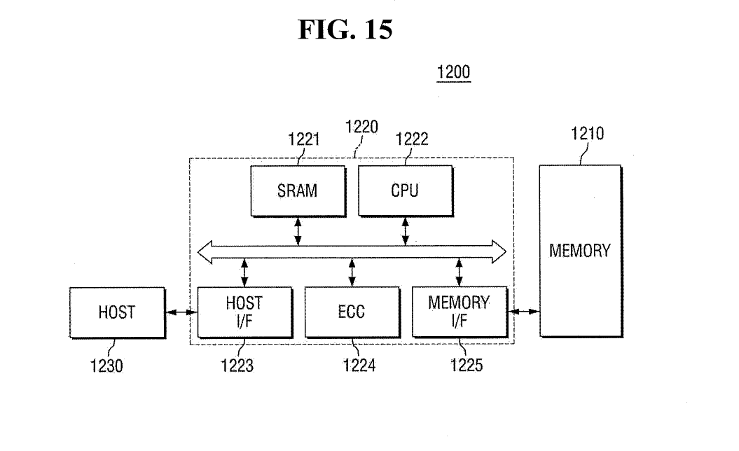

FIG. 15 is a block diagram of a memory card that includes a semiconductor device according to some embodiments of the present inventive concept.

Referring to FIG. 15, a memory 1210 that includes a semiconductor device according to some embodiments of the present inventive concept may be adopted in a memory card 1200. The memory card 1200 may include a memory controller 1220 that controls date exchange between a host 1230 and the memory 1210. An SRAM 1221 may be used as an operating memory of a central processing unit 1222. A host interface 1223 may include a protocol for the host 1230 to access the memory card 1200 to perform date exchange. An error correction code 1224 may detect and correct errors of data read from the memory 1210. A memory interface 1225 may interface with the memory 1210. The central processing unit 1222 may perform overall control operation related to data exchange with the memory controller 1220.

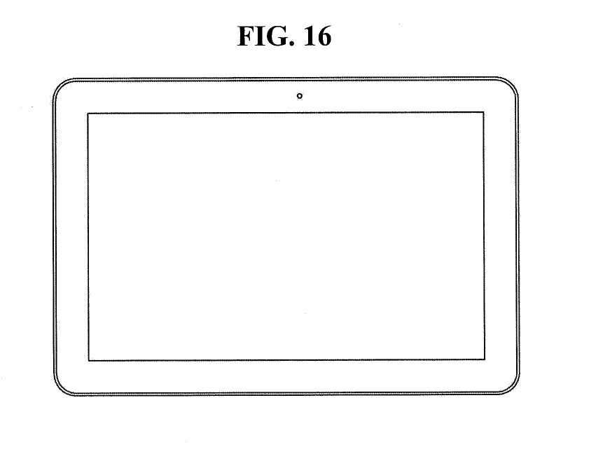

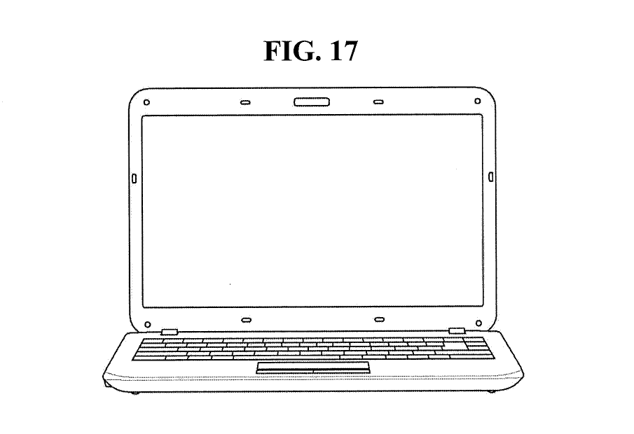

FIGS. 16 and 17 are views of exemplary semiconductor systems to which the semiconductor device according to some embodiments of the present inventive concept can be applied.

FIG. 16 illustrates a tablet PC, and FIG. 17 illustrates a notebook computer. At least one of the semiconductor devices according to some embodiments of the present inventive concept may be used in the tablet PC or the notebook computer. It is apparent to those of skilled in the art that the semiconductor device according to some embodiments of the present inventive concept can be applied even to other integrated circuit devices that have not been exemplified.

Although embodiments of the present inventive concepts have been described for illustrative purposes, those skilled in the art will appreciate that various modifications, additions and substitutions are possible, without departing from the scope and spirit of the inventive concepts as disclosed in the accompanying claims.

What is claimed is:

1. A semiconductor device comprising:
a substrate;
a lower electrode on the substrate;
a dielectric layer on the lower electrode;
an adhesion layer on the dielectric layer; and
an upper electrode on the adhesion layer,
wherein the adhesion layer contacts the dielectric layer and the upper electrode, and comprises a conductive material.

2. The semiconductor device of claim 1, wherein an upper surface of the adhesion layer is evenly formed to adhere to a lower surface of the upper electrode.

3. The semiconductor device of claim 1, wherein the conductive material has a band gap that is equal to or less than about 3.5 eV.

4. The semiconductor device of claim 1, wherein the conductive material comprises oxide.

5. The semiconductor device of claim 4, wherein the conductive material comprises NbOx or NbTiOx, where x is a real number that is equal to or larger than 2.

6. The semiconductor device of claim 1, wherein the adhesion layer comprises a composite layer.

7. The semiconductor device of claim 1, wherein at least one of the lower electrode and the upper electrode in turn comprises at least one of Ru, Ir, or Pt.

8. The semiconductor device of claim 1, wherein the dielectric layer comprises a high-k material.

9. A semiconductor device comprising:
a substrate;
a conductive lower electrode on the substrate and having a 3D structure;
a conformal dielectric layer on the lower electrode and including a high-k material;
an conformal adhesion layer on the dielectric layer; and
a conductive upper electrode on the conformal adhesion layer,
wherein the conformal adhesion layer contacts the conformal dielectric layer and the upper electrode, and comprises a conductive material.

10. The semiconductor device of claim 9, wherein an upper surface of the conformal adhesion layer is evenly formed to adhere to a lower surface of the upper electrode.

11. The semiconductor device of claim 9, wherein the conductive material has a band gap that is equal to or less than about 3.5 eV.

12. The semiconductor device of claim 9, wherein the conductive material comprises oxide.

13. The semiconductor device of claim 12, wherein the conductive material comprises NbOx or NbTiOx, where x is a real number that is equal to or larger than 2.

14. The semiconductor device of claim 9, wherein the conformal adhesion layer comprises a composite layer.

15. The semiconductor device of claim 9, wherein at least one of the lower electrode and the upper electrode in turn comprises at least one of Ru, Ir, or Pt.

16. A capacitor structure comprising:
a conductive lower electrode having a 3D structure on a substrate, the 3D structure including vertical portions that extend in a vertical direction of extension, relative to a horizontal direction of extension of the substrate;
a conformal dielectric layer on the lower electrode and including a high-k material, the conformal dielectric layer covering at least the vertical portions of the 3D structure;
a conformal adhesion layer on, and in contact with, the dielectric layer, the conformal adhesion layer covering at least portions of the conformal dielectric layer that in turn cover the vertical portions of the 3D structure, the conformal adhesion layer comprising a conductive material having an RMS surface roughness of less than about 1 nm; and
a conductive upper electrode on, and in contact with, the conformal adhesion layer.

17. The capacitor structure of claim 16, wherein the conductive material of the conformal adhesion layer has a band gap that is equal to or less than about 3.5 eV.

18. The capacitor structure of claim 16, wherein the conductive material of the conformal adhesion layer comprises oxide.

19. The capacitor structure of claim 18, wherein the conductive material of the conformal adhesion layer comprises NbOx or NbTiOx, where x is a real number that is equal to or larger than 2.

20. The capacitor structure of claim 16, wherein the conformal adhesion layer comprises a composite layer.
